(19) United States
(12) Patent Application Publication
(10) Pub. No.: US 2019/0267442 A1
(43) Pub. Date: Aug. 29, 2019

(54) DOUBLE-FACE DISPLAY PANEL AND DOUBLE-FACE DISPLAY DEVICE

(71) Applicant: Wuhan China Star Optoelectronics Semiconductor Display Technology Co., Ltd., Wuhan (CN)

(72) Inventor: Lei WANG, Shenzhen (CN)

(21) Appl. No.: 15/981,633

(22) Filed: May 16, 2018

Related U.S. Application Data
(63) Continuation of application No. PCT/CN2018/079572, filed on Mar. 20, 2018.

(30) Foreign Application Priority Data
Feb. 27, 2018 (CN) 201810165690.4

(51) Int. Cl. H01L 27/32; H01L 51/52

(52) U.S. Cl. CPC H01L 27/3267; H01L 27/3262; H01L 27/3248; H01L 2251/308; H01L 51/5206; H01L 2251/5315; H01L 2251/5307; H01L 51/5221

(57) ABSTRACT

Disclosed are a double-face display panel and a double-face display device. The double-face display panel comprises a plurality of pixel units arranged in an array, each of the pixel units including a thin film transistor, a front display pixel and a rear display pixel; the front display pixel comprises a first anode, a first light emitting layer and a first cathode; the rear display pixel comprises a second anode, a second light emitting layer and a second cathode; and the first anode and the second anode are electrically connected to a drain of the thin film transistor, respectively. Thereby, the present application can effectively reduce the number of wirings in the manufacturing process of the panel, and thus can reduce the impact on the pixel density due to the excessive number of wirings.

### CROSS-REFERENCE TO RELATED APPLICATION

This application is a continuing application of PCT Patent Application No. PCT/CN2018/079572 entitled “Double-face display panel and double-face display device”, filed on Mar. 20, 2018, which claims priority to Chinese Patent Application No. CN201810165690.4, filed on Feb. 27, 2018, both of which are hereby incorporated in its entireties by reference.

### FIELD OF THE INVENTION

The present application relates to a display technology field, and more particularly to a double-face display panel and a double-face display device.

### BACKGROUND OF THE INVENTION

Organic light-emitting diodes (OLEDs) possess advantages of wide color gamut, high contrast, self-luminescence, light and thin collapsibility, and have attracted widespread attentions in display and illumination applications.

Preparation of double-face display panels with OLEDs is a trend for the OLED applications. The double-face display can effectively expand the display area of the OLED panel and exert the advantages of lightness and thinness of the OLED panel. The double-face display OLED panels or the prior art mostly adopt transparent cathodes and transparent anodes, and one single sub pixel emits light from the top side and the bottom side. The OLED panel adopting the similar skill may have the characteristics of full transparency. However, since the light transmits from the top side to the bottom side, and vice versa, thus also possessing the defect of low contrast. Besides, an independent top-emission OLED device and bottom-emission OLED device may be adopted for the purpose of double-face display. The display contrast obtained by this arrangement is higher. However, the circuit layout is more complicated and more traces limit the increase of the pixel density. In this scheme, the number of pixels on one side is half of all pixels, so the pixel density is lower and the influence of the wiring on the pixel density becomes more significant.

### SUMMARY OF THE INVENTION

The present application provides a double-face display panel and a double-face display device, which can effectively reduce the number of wirings in the manufacturing process of the panel, and thus can reduce the impact on the pixel density due to the excessive number of wirings.

For solving the aforesaid technical issue, the present application provides a double-face display panel, comprising a plurality of pixel units arranged in an array, each of the pixel units including a thin film transistor, a front display pixel and a rear display pixel; wherein the front display pixel comprises a first anode, a first light emitting layer and a first cathode; the rear display pixel comprises a second anode, a second light emitting layer and a second cathode; and the first anode and the second anode are electrically connected to a drain of the thin film transistor, respectively; wherein the first cathode is an opaque or semi-transparent cathode for preventing light of the first light emitting layer from exiting from a rear side of the double-face display panel, and the second anode is an opaque or semi-transparent anode for preventing light of the second light emitting layer from exiting from a front side of the double-face display panel.

For solving the aforesaid technical issue, the present invention further provides a double-face display panel, comprising a plurality of pixel units arranged in an array, each of the pixel units including a thin film transistor, a front display pixel and a rear display pixel; wherein the front display pixel comprises a first anode, a first light emitting layer and a first cathode; the rear display pixel comprises a second anode, a second light emitting layer and a second cathode; and the first anode and the second anode are electrically connected to a drain of the thin film transistor, respectively.

For solving the aforesaid technical issue, the present invention further provides a double-face display device, wherein the double-face display device comprises a double-face display panel, including a plurality of pixel units arranged in an array, each of the pixel units including a thin film transistor, a front display pixel and a rear display pixel; wherein the front display pixel comprises a first anode, a first light emitting layer and a first cathode; the rear display pixel comprises a second anode, a second light emitting layer and a second cathode; and the first anode and the second anode are electrically connected to a drain of the thin film transistor, respectively.

The benefits of the present application are: a double-face display panel and a double-face display device are provided. By utilizing a single thin film transistor to control two adjacent sub pixels, the thickness of the display panel can be reduced while achieving the double-face display and it can effectively reduce the number of wirings in the manufacturing process of the panel, and thus can reduce the impact on the pixel density due to the excessive number of wirings.

### BRIEF DESCRIPTION OF THE DRAWINGS

FIG. 1 is a structural diagram of one embodiment of a double-face display panel of the present application;

FIG. 2 is a structural diagram of one embodiment of a first light emitting layer of the present application;

FIG. 3 is a circuit configuration diagram of one embodiment of a pixel unit of the present application;

FIG. 4 is a structural diagram of one embodiment of a double-face display device of the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments.

Based on the embodiments of the present application, all other embodiments to those of ordinary skill in the premise of no creative efforts obtained, should all be considered within the scope of protection of the present application.

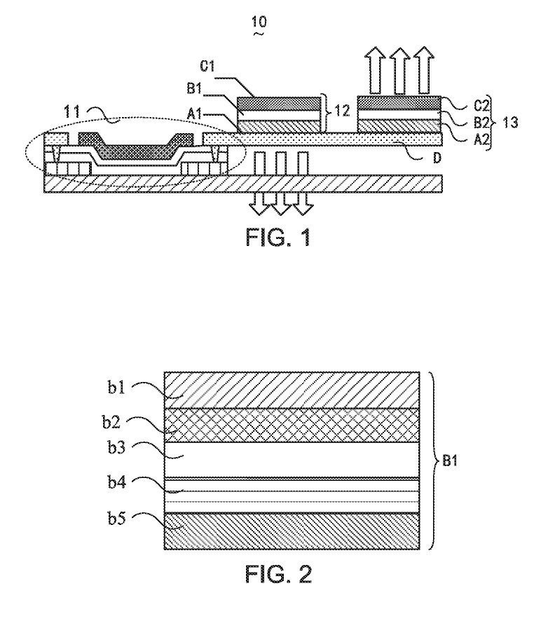

Please refer to FIG. 1. FIG. 1 is a structural diagram of one embodiment of a double-face display panel of the present application. As shown in FIG. 1, the double-face display panel 10 comprises a plurality of pixel units arranged in an array. Each of the pixel units includes a thin film transistor 11, a front display pixel 12 and a rear display pixel 13.

The front display pixel 12 comprises a first anode A1, a first light emitting layer B1 and a first cathode C1. The first light emitting layer B1 is arranged between the first anode A1 and the first cathode C1. In the specific embodiment, the first cathode C1 is an opaque or semi-transparent cathode for preventing light of the first light emitting layer B1 from exiting from a rear side of the double-face display panel. Meanwhile, the first cathode C1 can further block the incident ambient light from a rear side of the double-face display panel 10 and improve the display contrast.

The first anode A1 is a transparent anode. Namely, the first anode A1 is a fully transparent structure, which can be made of a transparent material, and specifically can be made of indium tin oxide (ITO).

Please refer to FIG. 2. FIG. 2 is a structural diagram of one embodiment of a first light emitting layer of the present application. As shown in FIG. 2, the first light emitting layer B1 can comprise an organic light emitting diode, which specifically comprises an electron injection layer b1, an electron transport layer b2, an organic light emitting diode functional layer b3, a hole transport layer b4 and a hole injection layer b5 that are successively stacked from top to bottom. The first cathode C1 covers on the electron injection layer b1. The first anode A1 covers on the lower side of the hole injection layer b5. The voltage between the first anode A1 and the first cathode C1 may cause holes to be injected into the OLED functional layer b3 from the hole injection layer b5 and the hole transport layer b4. Meanwhile, electrons are injected into the OLED functional layer b3 from the electron injection layer b1 and the electron transport layer b2. The holes and electrons bump into each other in the OLED functional layer b3 to excite the organic material of the OLED functional layer b3 to emit light. Certainly, in the present application, the structure of the PM-OLED is only illustrated for description. In other embodiments, other types of OLEDs may also be used.

Please refer to FIG. 1. The rear display pixel 13 comprises a second anode A2, a second light emitting layer B2 and a second cathode C2. The second light emitting layer B2 is arranged between the second anode A2 and the second cathode C2. In the specific embodiment, the second cathode C2 is an opaque or semi-transparent cathode for preventing light of the second light emitting layer B2 from exiting from a front side of the double-face display panel. Meanwhile, the second cathode C2 can further block the incident ambient light from a front side of the double-face display panel 10 and improve the display contrast.

The second light emitting layer B2 may comprise an organic light emitting diode and has a structure similar to that of the first light emitting layer B1 in FIG. 2. For the detailed structure, refer to FIG. 2 and the specific description as aforementioned, which will not be repeated herein.

The first anode A1 and the second anode A2 are electrically connected to a drain of the thin film transistor 11, respectively. In the specific embodiment, the front display pixel 12 and the rear display pixel 13 are respectively driven by the same thin film transistor. Thus, both have the same drive current so that the light emission brightnesses of the two are the same.

In the aforesaid embodiment, by integrating the front display pixels and the rear display pixels on the same driving back plate, the thickness of the display panel can be reduced while realizing the double-face display. The area of the double-face display can be effectively improved.

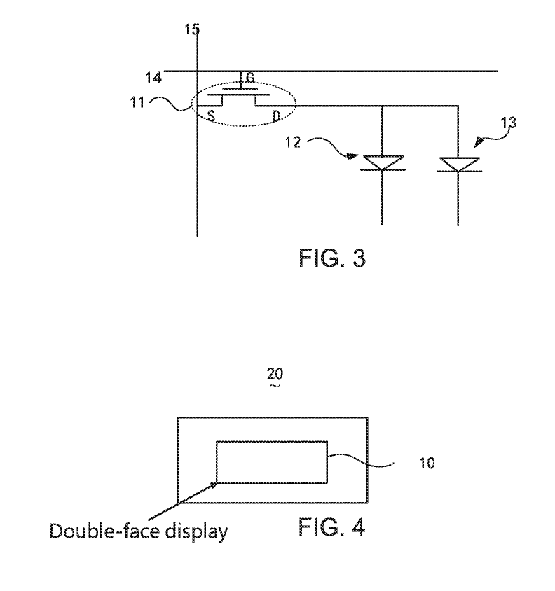

Please refer to FIG. 3. FIG. 3 is a circuit configuration diagram of one embodiment of a pixel unit of the present application. As shown in FIG. 3, each of the pixel units in this application comprises a thin film transistor 11, a front display pixel 12 and a rear display pixel 13. As shown in figure, the thin film transistor 11 comprises a gate G, a source S and a drain D. The gate G of the thin film transistor 11 is connected to the scan line 14, the source S of the thin film transistor 11 is connected to the data line 15 and the drain D of the thin film transistor 11 is connected to the front display pixel 12 and the rear display pixel 13, respectively.

The following is a brief description of the working principle of the aforesaid embodiment:

The scan signal of the scan line 14 activates the gate G of the thin film transistor 11, and the data line 15 writes the data signal to the front display pixel 12 and the back display pixel 13, respectively. A voltage difference is generated between the first anode A1 and the first cathode C1 in the front display pixel 12 and between the second anode A2 and the second cathode C2 in the rear display pixel 13 to respectively excite the first light emitting layer B1 and the second light emitting layer B2 to emit light. In the present application, since the first cathode C1 is an opaque or semi-transparent cathode to prevent the light of the first light emitting layer B1 from exiting from the rear side of the double-face display. The second anode A2 is an opaque or semi-transparent cathode to further block the incident ambient light from the front side of the double-face display panel 10 to realize the double-face display.

Furthermore, the front display pixel 12 and the rear display pixel 13 are respectively driven by the same thin film transistor 11. The same drive current flows into the front display pixel 12 and the rear display pixel 13. Thus, the brightnesses of the two are the same to have better contrasts.

Thereby, by utilizing a single thin film transistor to control two adjacent sub pixels, it can effectively reduce the number of wirings in the manufacturing process of the panel, and thus can reduce the impact on the pixel density due to the excessive number of wirings.

Please refer to FIG. 4. FIG. 4 is a structural diagram of one embodiment of a double-face display device of the present application. As shown in FIG. 4, the double-face display device 20 in the present application comprises the foregoing double-face display panel 10 according to any of the embodiments.

Please refer to FIG. 1. The double-face display panel 10 comprises a plurality of pixel units arranged in an array. Each of the pixel units includes a thin film transistor 11, a front display pixel 12 and a rear display pixel 13.

The front display pixel 12 comprises a first anode A1, a first light emitting layer B1 and a first cathode C1. In the specific embodiment, the first cathode C1 is an opaque or semi-transparent cathode for preventing light of the first light emitting layer B1 from exiting from a rear side of the double-face display panel. Meanwhile, the first cathode C1 can further block the incident ambient light from a rear side of the double-face display panel 10 and improve the display contrast.

The rear display pixel 13 comprises a second anode A2, a second light emitting layer B2 and a second cathode 02. The second light emitting layer B2 is arranged between the second anode A2 and the second cathode C2. In the specific embodiment, the second cathode C2 is an opaque or semi-transparent cathode for preventing light of the second light emitting layer B2 from exiting from a front side of the double-face display panel. Meanwhile, the second cathode C2 can further block the incident ambient light from a front side of the double-face display panel 10 and improve the display contrast.

The first anode A1 and the second anode A2 are electrically connected to a drain of the thin film transistor 11, respectively. In the specific embodiment, the front display pixel 12 and the rear display pixel 13 are respectively driven by the same thin film transistor. Thus, both have the same drive current so that the light emission brightnesses of the two are the same.

For the specific structure and working principle of the front display pixels and the rear display pixels in the aforesaid embodiment, please refer to the specific description in the above embodiment, which will not be repeated here.

In the aforesaid embodiments, by utilizing a single thin film transistor to control two adjacent sub pixels and integrating the front display pixel and the rear display panel on the same driving back plate, the thickness of the display panel can be reduced while achieving the double-face display and it can effectively reduce the number of wirings in the manufacturing process of the panel, and thus can reduce the impact on the pixel density due to the excessive number of wirings.

In conclusion, those skilled in the art can easily understand that in the double-face display panel and the double-face display device provided in the present application, by utilizing a single thin film transistor to control two adjacent sub pixels, the thickness of the display panel can be reduced while achieving the double-face display and it can effectively reduce the number of wirings in the manufacturing process of the panel, and thus can reduce the impact on the pixel density due to the excessive number of wirings.

Above are only specific embodiments of the present invention, the scope of the present application is not limited to this, and to any persons who are skilled in the art, change or replacement which is easily derived should be covered by the protected scope of the application. Thus, the protected scope of the application should go by the subject claims.

What is claimed is:

1. A double-face display panel, comprising a plurality of pixel units arranged in an array, each of the pixel units including a thin film transistor, a front display pixel and a rear display pixel; wherein
the front display pixel comprises a first anode, a first light emitting layer and a first cathode; the rear display pixel comprises a second anode, a second light emitting layer and a second cathode; and the first anode and the second anode are electrically connected to a drain of the thin film transistor, respectively;
wherein the first cathode is an opaque or semi-transparent cathode for preventing light of the first light emitting layer from exiting from a rear side of the double-face display panel, and the second anode is an opaque or semi-transparent anode for preventing light of the second light emitting layer from exiting from a front side of the double-face display panel.

2. The double-face display panel according to claim 1, wherein the first anode is a transparent anode and the second anode is a transparent anode.

3. The double-face display panel according to claim 1, wherein the first light emitting layer and the second light emitting layer are organic light emitting diodes.

4. A double-face display panel, comprising a plurality of pixel units arranged in an array, each of the pixel units including a thin film transistor, a front display pixel and a rear display pixel; wherein
the front display pixel comprises a first anode, a first light emitting layer and a first cathode; the rear display pixel comprises a second anode, a second light emitting layer and a second cathode; and the first anode and the second anode are electrically connected to a drain of the thin film transistor, respectively.

5. The double-face display panel according to claim 4, wherein the first cathode is an opaque or semi-transparent cathode for preventing light of the first light emitting layer from exiting from a rear side of the double-face display panel.

6. The double-face display panel according to claim 4, wherein the second anode is an opaque or semi-transparent anode for preventing light of the second light emitting layer from exiting from a front side of the double-face display panel.

7. The double-face display panel according to claim 4, wherein the first anode is a transparent anode and the second anode is a transparent anode.

8. The double-face display panel according to claim 4, wherein the first light emitting layer and the second light emitting layer are organic light emitting diodes.

9. A double-face display device, wherein the double-face display device comprises a double-face display panel, including a plurality of pixel units arranged in an array, each of the pixel units including a thin film transistor, a front display pixel and a rear display pixel; wherein
the front display pixel comprises a first anode, a first light emitting layer and a first cathode; the rear display pixel comprises a second anode, a second light emitting layer and a second cathode; and the first anode and the second anode are electrically connected to a drain of the thin film transistor, respectively.

10. The double-face display device according to claim 9, wherein the first cathode is an opaque or semi-transparent cathode for preventing light of the first light emitting layer from exiting from a rear side of the double-face display panel.

11. The double-face display device according to claim 9, wherein the second anode is an opaque or semi-transparent anode for preventing light of the second light emitting layer from exiting from a front side of the double-face display panel.

12. The double-face display device according to claim 9, wherein the first anode is a transparent anode and the second anode is a transparent anode.

13. The double-face display device according to claim 9, wherein the first light emitting layer and the second light emitting layer are organic light emitting diodes.
